(19) United States
(12) Patent Application Publication
(10) Pub. No.: US 2023/0197628 A1
(43) Pub. Date: Jun. 22, 2023

(54) METHOD FOR MANUFACTURING SEMICONDUCTOR DEVICE, AND SEMICONDUCTOR SUBSTRATE

(71) Applicant: SUMITOMO ELECTRIC DEVICE INNOVATIONS, INC., Yokohama-shi (JP)

(72) Inventor: Tadahiro HACHUDA, Yokohama-shi (JP)

(73) Assignee: SUMITOMO ELECTRIC DEVICE INNOVATIONS, INC., Yokohama-shi (JP)

(21) Appl. No.: 18/172,077

(22) Filed: Feb. 21, 2023

Related U.S. Application Data
(62) Division of application No. 17/191,819, filed on Mar. 4, 2021.

(30) Foreign Application Priority Data
Mar. 31, 2020 (JP) 2020-062906

(51) Int. Cl. H01L 23/544; H01L 31/0304; H01L 31/0352; H01L 31/18; H01L 33/00; H01L 33/06; H01L 33/30

(52) U.S. Cl. CPC H01L 23/544; H01L 31/184; H01L 31/186; H01L 31/0304; H01L 31/035236; H01L 33/06; H01L 33/30; H01L 33/0062; H01L 33/0095; H01L 2223/5446

(57) ABSTRACT

A method for manufacturing a semiconductor device includes selectively forming an insulating film on a region of a substrate serving as a scribe line; and forming a first semiconductor layer in a state where a cavity is provided on the insulating film. The cavity is buried in the first semiconductor layer.

### CROSS-REFERENCE TO RELATED APPLICATION

This application claims priority based on Japanese Patent Application No. 2020-062906 filed on Mar. 31, 2020, and the entire contents of the Japanese patent application are incorporated herein by reference.

### FIELD OF THE INVENTION

The present disclosure relates to a method for manufacturing a semiconductor device, and a semiconductor substrate.

### BACKGROUND ART

After a semiconductor layer and other components are formed on a substrate (wafer), the wafer is divided to manufacture semiconductor devices such as light emitting elements and light receiving elements. For example, there is known a technique for dividing the wafer with a blade of a dicing apparatus (e.g. Japanese Laid-open Patent Publication No. 2008-270627).

### SUMMARY OF THE INVENTION

A method for manufacturing a semiconductor device according a present disclosure includes: forming an insulating film on a region of a substrate serving as a scribe line; forming a first semiconductor layer in a state where a cavity is provided on the insulating film; forming a second semiconductor layer on the first semiconductor layer; and dividing the substrate, the first semiconductor layer and the second semiconductor layer into a plurality of pieces by pressing the substrate at a position corresponding to the region serving as the scribe line on a surface of the substrate opposite to a surface on which the first semiconductor layer is formed.

A semiconductor substrate according a present disclosure includes a semiconductor layer having a cavity embedded along a region serving as a scribe line.

### BRIEF DESCRIPTION OF THE DRAWINGS

FIG. 1A is a cross-sectional view illustrating a semiconductor device according to a first embodiment.

FIG. 1B is a plan view illustrating the semiconductor device.

FIG. 2 is a plan view illustrating a method for manufacturing the semiconductor device.

FIG. 3A is a cross-sectional view illustrating the method for manufacturing the semiconductor device.

FIG. 3B is a cross-sectional view illustrating the method for manufacturing the semiconductor device.

FIG. 4A is a cross-sectional view illustrating the method for manufacturing the semiconductor device.

FIG. 4B is a cross-sectional view illustrating the method for manufacturing the semiconductor device.

FIG. 5A is a cross-sectional view illustrating the method for manufacturing the semiconductor device.

FIG. 5B is a cross-sectional view illustrating the method for manufacturing the semiconductor device.

FIG. 6A is a cross-sectional view illustrating the method for manufacturing the semiconductor device.

FIG. 6B is a cross-sectional view illustrating the method for manufacturing the semiconductor device.

FIG. 7A is a cross-sectional view illustrating the method for manufacturing the semiconductor device.

FIG. 7B is a cross-sectional view illustrating the method for manufacturing the semiconductor device.

FIG. 8A is a cross-sectional view illustrating the method for manufacturing the semiconductor device.

FIG. 8B is a cross-sectional view illustrating the method for manufacturing the semiconductor device.

FIG. 9 is a cross-sectional view illustrating a semiconductor device according to a second embodiment.

FIG. 10A is a cross-sectional view illustrating the method for manufacturing the semiconductor device.

FIG. 10B is a cross-sectional view illustrating the method for manufacturing the semiconductor device.

FIG. 11A is a cross-sectional view illustrating the method for manufacturing the semiconductor device.

FIG. 11B is a cross-sectional view illustrating the method for manufacturing the semiconductor device.

FIG. 12A is a cross-sectional view illustrating the method for manufacturing the semiconductor device.

FIG. 12B is a cross-sectional view illustrating the method for manufacturing the semiconductor device.

FIG. 13 is a cross-sectional view illustrating the method for manufacturing the semiconductor device.

### DESCRIPTION OF EMBODIMENTS

Dividing the substrate may cause foreign matters such as substrate fragments to be generated. The foreign matters may adhere to the chip, resulting in poor appearance and characteristic defects. Therefore, it is an object of the present disclosure to provide a method for manufacturing a semiconductor device, and a semiconductor substrate that are capable of suppressing the generation of the foreign matters.

### Description of Embodiments of the Present Disclosure

First, the contents of embodiments of the present disclosure will be listed and described.

A method for producing a semiconductor optical device according to an embodiment of the present disclosure includes: (1) forming an insulating film on a region of a substrate serving as a scribe line, forming a first semiconductor layer in a state where a cavity is provided on the insulating film, forming a second semiconductor layer on the first semiconductor layer, and dividing the substrate, the first semiconductor layer and the second semiconductor layer into a plurality of pieces by pressing the substrate at a position corresponding to the region serving as the scribe line on a surface of the substrate opposite to a surface on which the first semiconductor layer is formed. The first semiconductor layer grows so as to extend over the insulating film. A portion of the first semiconductor layer that extends over the insulating film is more likely to crack than the other portions. The substrate can be divided along the scribe line, and the generation of foreign matters due to the division can be suppressed.

(2) The method may further include etching the substrate using the insulating film as a mask to form a mesa before forming the first semiconductor layer. The first semiconductor layer grows so as to extend over the insulating film. The portion of the first semiconductor layer that extends over the insulating film is more likely to crack than the other portions. The substrate can be divided along the scribe line, and the generation of the foreign matters due to the division can be suppressed.

(3) The first semiconductor layer may be formed by applying a growth gas of phosphine and trimethylindium, and the embedded layer may be formed by applying a growth gas of trimethylindium and methyl chloride.

(4) A semiconductor device according to an embodiment of the present disclosure includes a semiconductor layer provided on a substrate; and electrodes provided on the semiconductor layer. The semiconductor layer has a recess embedded along a region serving as a scribe line. The substrate semiconductor can be divided along the region serving as the scribe line, and the generation of the foreign matters due to the division can be suppressed.

(5) The semiconductor device may include an insulating film formed inside the recess.

(6) The semiconductor device may be a light emitting element or a light receiving element.

(7) A semiconductor substrate according to an embodiment of the present disclosure includes a semiconductor layer having a cavity embedded along a region serving as a scribe line. The substrate semiconductor can be divided along the region serving as the scribe line, and the generation of the foreign matters due to the division can be suppressed.

(8) The semiconductor device may include an insulating film formed inside the recess.

### Details of Embodiments of the Present Disclosure

A description will be given of embodiments of the method for manufacturing the semiconductor device, and the semiconductor substrate according to embodiments of the present disclosure, with reference to drawings. The present disclosure is not limited to the specifically disclosed embodiments and variations but may include other embodiments and variations without departing from the scope of the present invention.

### First Embodiment

### Semiconductor Device

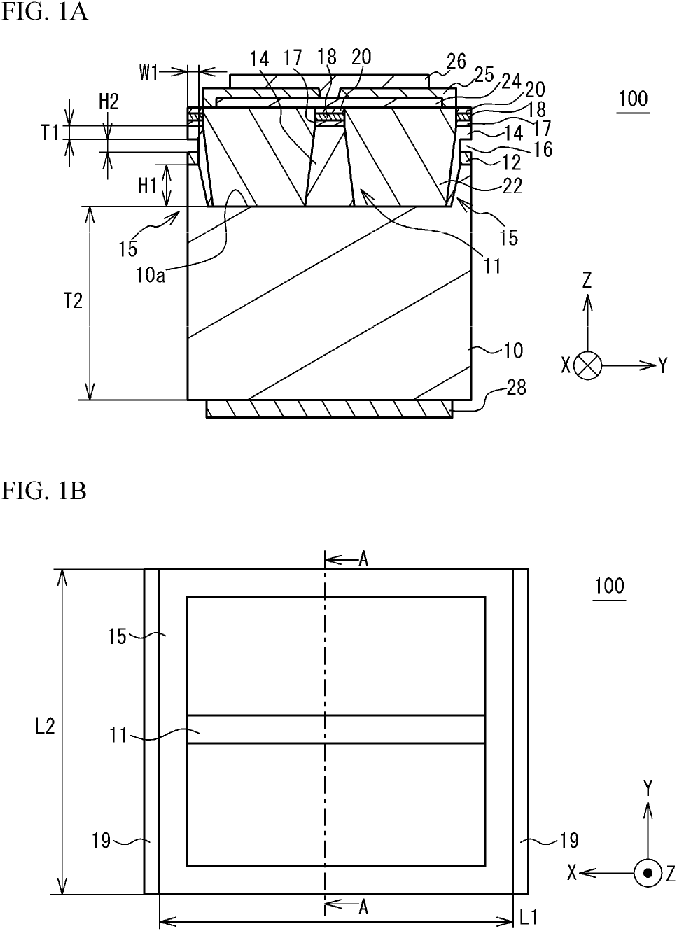

FIG. 1A is a cross-sectional view illustrating a semiconductor device 100 according to a first embodiment, and illustrates a cross section along line A-A in FIG. 1B. FIG. 1B is a plan view illustrating the semiconductor device 100, and is a schematic view as described below. An X-axis direction, a Y-axis direction and a Z-axis direction are orthogonal to each other. The X-axis direction and the Y-axis direction are directions of two sides of the semiconductor device 100 that are orthogonal to each other. The Z-axis direction is a stacking direction of a semiconductor layer in the semiconductor device 100.

As illustrated in FIGS. 1A and 1B, the semiconductor device 100 includes a mesa 11 (second mesa) and a mesa 15. FIG. 1B illustrates only the mesas 11 and 15, and reflective films 19 in the semiconductor device 100. As shown in FIG. 1B, the mesa 15 is provided so as to surround an outer periphery of the semiconductor device 100. The mesa 15 extends in the X-axis direction and the Y-axis direction. The mesa 11 is provided at the center of the semiconductor device 100. The mesa 11 extends in the X-axis direction. For example, the reflective films 19 made of silicon nitride (SiN) are provided on two sides of the semiconductor device 100 (i.e., end faces on the X-axis side) extending in the Y-axis direction. A length L1 of a side in the X-axis direction and a length L2 of a side in the Y-axis direction are 300 µm, for example.

As illustrated in FIG. 1A, the semiconductor device 100 is a light emitting element that includes a substrate 10, insulating films 12 and 25, a semiconductor layer 14 (corresponding to a first semiconductor layer), a semiconductor layer 22, an active layer 18, a clad layer 17 and 20, a contact layer 24, and electrodes 26 and 28. The semiconductor layer 22, the active layer 18 and the clad layer 17 and 20 correspond to a second semiconductor layer.

The mesa 11 includes the semiconductor layer 14, the clad layer 17, the active layer 18 and the clad layer 20. In the mesa 11, the clad layer 17 is provided on an upper surface of the semiconductor layer 22, the active layer 18 is provided on an upper surface of the clad layer 17, and the clad layer 20 is provided on an upper surface of the active layer 18.

The mesa 15 is formed on the substrate 10. In the mesa 15, the insulating film 12 is provided on an upper surface of the substrate 10. The semiconductor layer 14 is provided from a side surface on the inner side (i.e., mesa 11 side) of the substrate 10 to an upper side of the insulating film 12. A recess 16 is formed between the upper surface of the insulating film 12 and the semiconductor layer 14. That is, a part of each side surface of the semiconductor device 100 is recessed inward, and the insulating film 12 is embedded in the recess 16. The clad layer 17, the active layer 18 and the clad layer 20 are stacked in this order on the semiconductor layer 14.

A surface 10a of the substrate 10 spreads between the mesa 11 and the mesa 15. A height H1 of the mesa 15 from the surface 10a is 2 µm or more, for example. A size (i.e., a height) H2 of the recess 16 is 0.5 µm, for example. A thickness T1 of the semiconductor layer 14 on the recess 16 is 2 µm, for example. A width W1 of each of the insulating film 12 and the recess 16 is 1 µm or more and 2 µm or less, for example. A thickness T2 from a lower surface of the substrate 10 to the surface 10a is 100 µm, for example.

The semiconductor layer 22 is an embedded layer that is provided on the surface 10a of the substrate 10 and embeds the mesas 11 and 15. The contact layer 24 is provided on the semiconductor layer 22 and the mesa 11. The insulating film 25 is provided on the contact layer 24 and the semiconductor layer 22, and the electrode 26 is provided on the insulating film 25. The electrode 26 contacts the contact layer 24 through an opening of the insulating film 25 and is electrically connected to the contact layer 24. The electrode 28 is provided on the lower surface of the substrate 10 and is electrically connected to the substrate 10.

The substrate 10 is a semiconductor substrate made of n-type indium phosphide (n-InP), for example. The semiconductor layer 14 is made of InP, for example. The semiconductor layer 22 is made of, for example, InP doped with iron (Fe), and is a layer having a resistance higher than other semiconductor layers. The substrate 10, and the semiconductor layers 14 and 22 may include a semiconductor other than InP along with InP.

The active layer 18, for example, includes multiple layers in which a plurality of indium gallium arsenide (InGaAs) layers and a plurality of indium gallium phosphate (InGaAsP) layers are stacked, and has a multiple quantum well (MQW) structure. The clad layer 17 is made of n-InP having a thickness of 0.3 µm, for example. The clad layer 20 is made of p-InP having a thickness of 0.3 µm, for example. The contact layer 24 is made of p-InGaAsP having a thickness of 1.5 µm, for example. The active layer 18, the clad layers 17 and 20, and the contact layer 24 may be made of a semiconductor other than the above.

The insulating film 12 is made of an insulator such as silicon nitride (SiN) or silicon oxide (SiO₂) having a thickness of 200 nm or more and 300 nm or less, for example. The insulating film 25 is a passivation film made of an insulator such as SiN or SiO₂. The electrodes 26 and 28 are made of a metal such as gold (Au). The electrode 26 is a p-electrode, for example, and the electrode 28 is an n-electrode, for example.

An optical gain is obtained by applying a voltage to the electrodes 26 and 28 and injecting carriers into the active layer 18. The light emitted from the active layer 18 propagates in the X-axis direction along the mesa 11. Each of the reflective films 19 illustrated in FIG. 1B reflects a part of the light emitted from the active layer 18 and transmits a remaining part of the light.

### Manufacturing Method

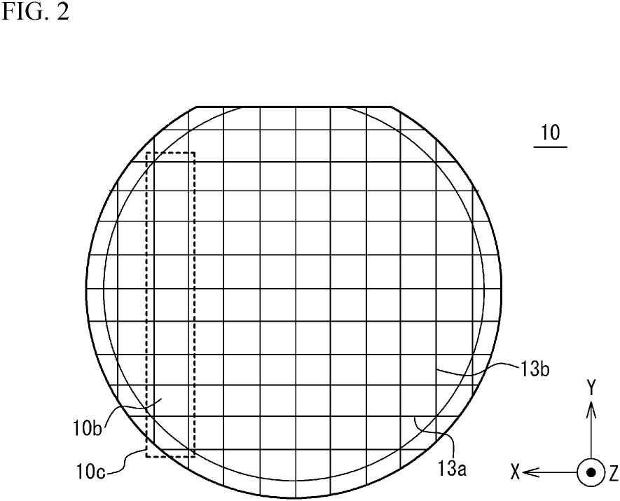

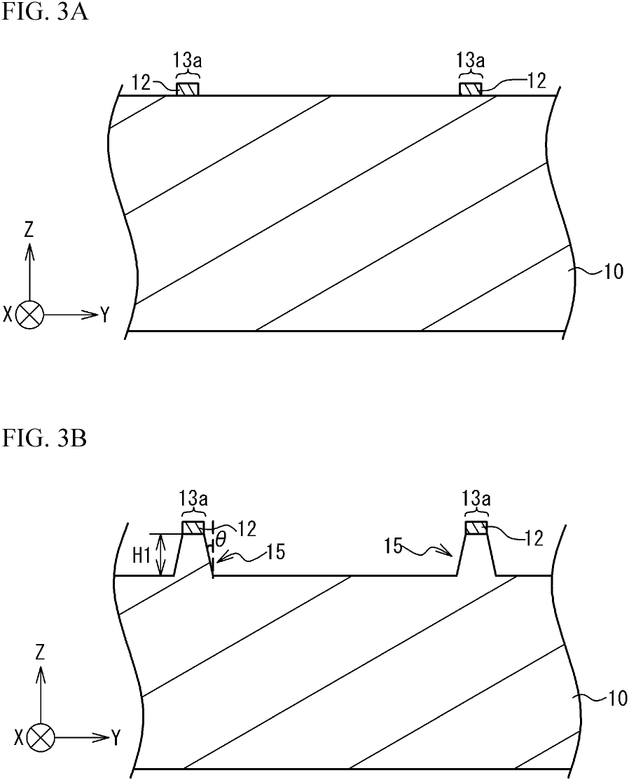

FIG. 2 is a plan view illustrating a method for manufacturing the semiconductor device 100. FIGS. 3A to 8B are cross-sectional views illustrating the method for manufacturing the semiconductor device 100, and illustrate a cross section corresponding to FIG. 1A.

A manufacturing process of the semiconductor device 100 is performed on the substrate 10 in a wafer state as illustrated in FIG. 2. The upper surface of the substrate 10 is a (001) surface of InP. A plurality of regions 13a and 13b illustrated by solid lines on the substrate 10 are regions serving as scribe lines. Each of the plurality of regions 13a extends from one end of the wafer to the other end in the X-axis direction (i.e., a [01-1] direction of the substrate 10, or a direction of an orientation flat). Each of the plurality of regions 13b extends from one end of the wafer to the other end in the Y-axis direction (i.e., a [01-1-] direction of the substrate 10, or a direction of an index flat). The region 13a and the region 13b are orthogonal to each other. In the middle of the manufacturing process, an array 10c in which a plurality of regions 10b are connected together is formed. Finally, a single region 10b surrounded by the regions 13a and 13b becomes one chip, i.e., the semiconductor device 100.

FIGS. 3A-8B illustrate the single region 10b of FIG. 2. As illustrated in FIG. 3A, the insulating film 12 is formed in the region 13a of the upper surface of the substrate 10, and the insulating film 12 is also formed in the region 13b at the same time (not illustrated). For example, the insulating film 12 is formed by a chemical vapor deposition (CVD) method or the like. Specifically, the insulating film 12 is formed in the regions 13a and 13b by performing resist patterning by photolithography, and wet etching with HF (hydrogen fluoride). The resist is removed.

As illustrated in FIG. 3B, the mesas 15 are formed on the substrate 10 by dry etching with, for example, silicon tetrachloride gas (SiCl₄)/argon (Ar) using the insulating film 12 as a mask. Examples of conditions of the dry etching are as follows.

Antenna power: 200-250 W
Bias power: 100-200 W
Flow rate of SiCl₄: 5 to 10 sccm (8.335 × 10⁻⁸ to 16.67 × 10⁻⁸ m³/s)
Flow rate of Ar: 40 to 50 sccm (66.68 × 10⁻⁸ to 83.35 × 10⁻⁸ m³/s)
Pressure: 0.5 to 1.0 Pa
Temperature of the substrate 10: 180 to 220° C.
The mesas 15 are formed in the regions 13a and 13b illustrated in FIG. 2. The height H1 of the mesa 15 is 2 µm or more, for example. An inclination angle θ of the side surface of the mesa 15 with respect to the Z-axis direction is 10°, for example. After the formation of the mesa 15, the insulating film 12 is not removed, but remains on the mesa 15.

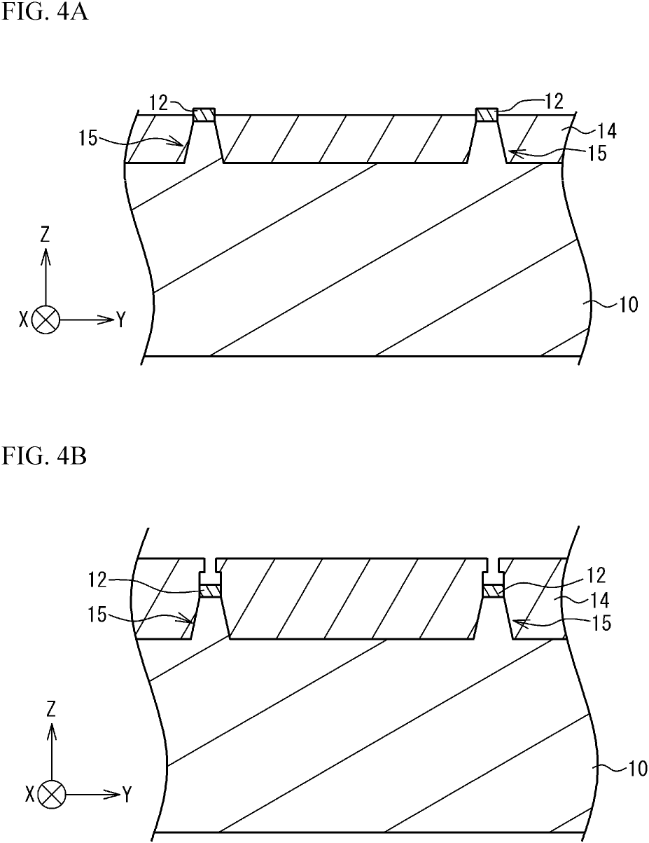

As illustrated in FIGS. 4A and 4B, the semiconductor layer 14 of InP is epitaxially grown by a metalorganic vapor phase epitaxy (MOVPE) method using, for example, phosphine (PH₃)/ trimethylindium (TMI) as a raw material gas. Examples of conditions of the growth are as follows.

Flow rate of PH₃ > Flow rate of TMI
Growth temperature: 650° C.
Growth pressure: 100 mbar
Growth rate of the semiconductor layer 14: 2 µm/h

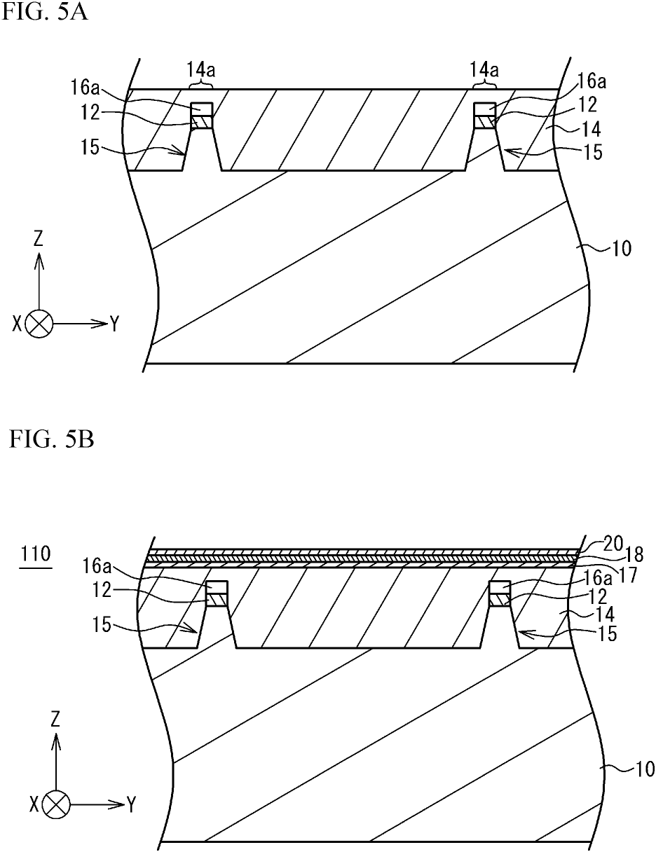

As illustrated in FIG. 4A, the semiconductor layer 14 grows upward from the upper surface of the substrate 10 and embeds the mesas 15. As illustrated in FIG. 4B, the semiconductor layer 14 reaches a position above the insulating film 12 and grows so as to laterally protrude from the outside to the inside of the insulating film 12. As illustrated in FIG. 5A, the semiconductor layer 14 is formed so as to embed the mesa 15 and cover the insulating film 12. Each of portions 14a of the semiconductor layer 14 that overlaps with the insulating film 12 in the thickness direction (i.e., the Z-axis direction) is a portion in which growth in the lateral direction is promoted, as described later. The insulating film 12 is embedded inside the semiconductor layer 14. A cavity 16a is formed between the insulating film 12 and the semiconductor layer 14.

In the upward crystal growth illustrated in FIG. 4A, the semiconductor layer 14 grows mainly in a (100) direction. On the other hand, the semiconductor layer 14 also grows laterally so as to protrude over the mesa 15 and the insulating film 12, as illustrated in FIG. 4B. Such growth is promoted more laterally than vertically, unlike the upward crystal growth. It is presumed that the growth with weak surface orientation dependence is performed on the mesa 15. As a result of the weak surface orientation dependence, the semiconductor layer 14 grows in also the lateral direction, so that the cavity 16a is easily formed. As illustrated in FIG. 5A, growth portions promoted laterally in the semiconductor layer 14 are referred to as the portions 14a. Each of the portions 14a of the semiconductor layer 14 has a crystal structure different from the other portions of the semiconductor layer 14. The portion 14a is formed in each of the regions 13a and 13b illustrated in FIG. 2.

As illustrated in FIG. 5B, the clad layer 17, the active layer 18 and the clad layer 20 are epitaxially grown in this order by the MOVPE method, for example. A semiconductor substrate 110 is formed by the steps up to FIG. 5B.

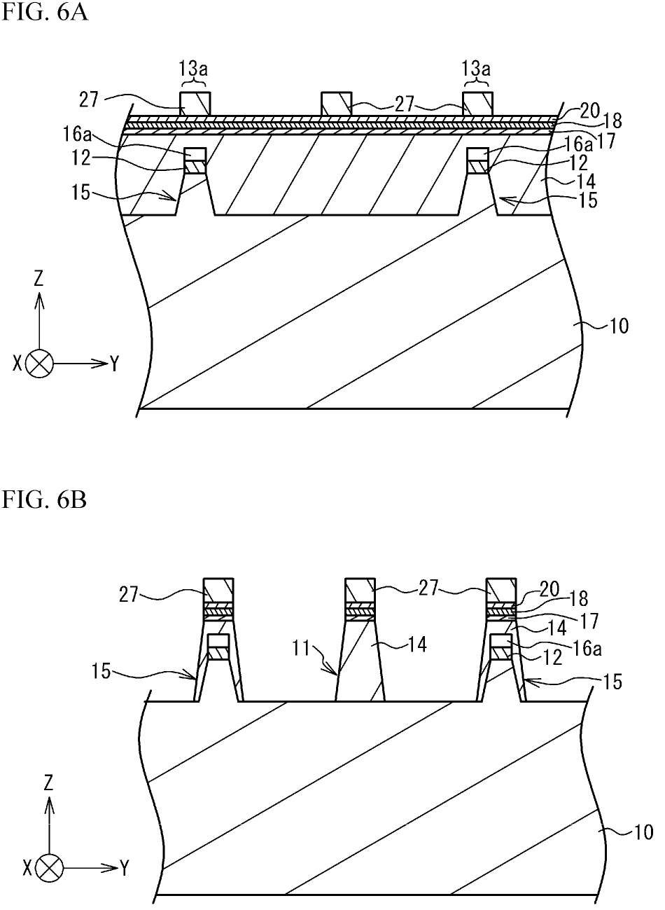

As illustrated in FIG. 6A, insulating films 27 (third insulating film) are formed on the upper surface of the clad layer 20 by the CVD method, the resist patterning or the like, for example. The insulating films 27 are provided in the regions 13a and the regions 13b (here, the regions 13b are not illustrated in FIG. 6A) serving as the scribe line. Further, the insulating film 27 is provided in a region surrounded by the regions 13a and 13b.

As illustrated in FIG. 6B, dry etching is performed with, for example, SiCl4/Ar using the insulating films 27 as the mask. The conditions of the dry etching in FIG. 6B are the same as those of the dry etching in the step of forming the mesa 15, for example. Portions protected by the insulating film 27 in the semiconductor layer 14, the clad layers 17 and 20, and the active layer 18 remain, and unprotected portions are removed. The mesa 11 is formed at a position between the mesas 15. The mesa 15 is covered from the side surface to the upper surface with the semiconductor layer 14. The insulating film 12 and the cavity 16a are embedded inside the semiconductor layer 14. The semiconductor layer 14 grows so as to cover the insulating film 12 and the cavity 16a. The clad layer 17, the active layer 18 and the clad layer 20 are stacked in this order on the semiconductor layer 14.

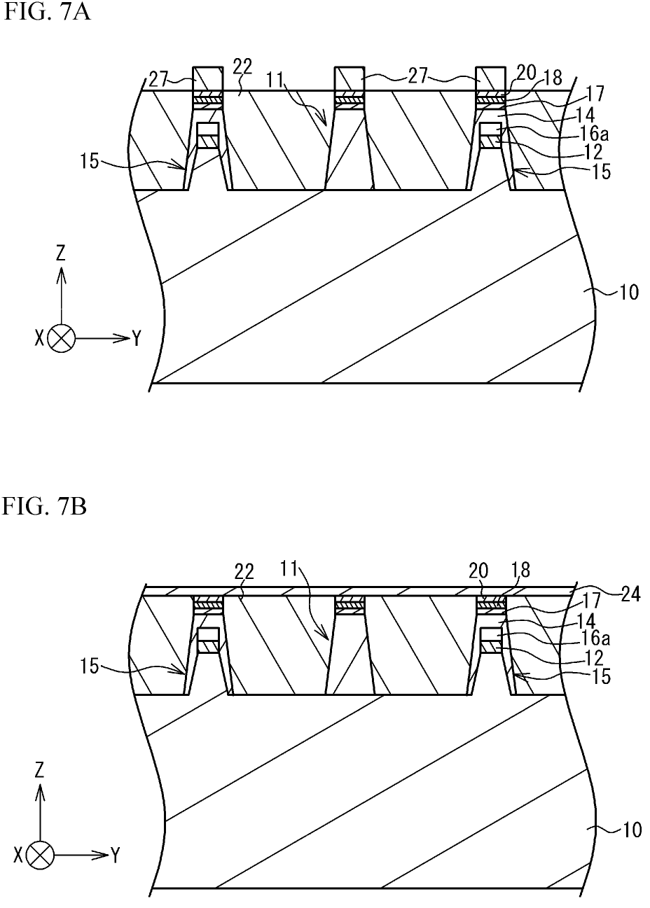

As illustrated in FIG. 7A, the semiconductor layer 22 that embeds the mesas 11 and 15 is epitaxially grown by the MOVPE method, for example. Among the growth conditions of the semiconductor layer 22, the growth temperature and the growth rate are the same as those of the semiconductor layer 14. The raw material gas is PH₃/TMI gas. The flow rate of PH₃ is 600 sccm, for example, and the flow rate of TMI is 500 sccm, for example. The upper surface of the semiconductor layer 22 is located at the same height as the upper surface of the clad layer 20. After the growth of the semiconductor layer 22, the insulating film 27 is removed by etching using hydrogen fluoride (HF) or the like.

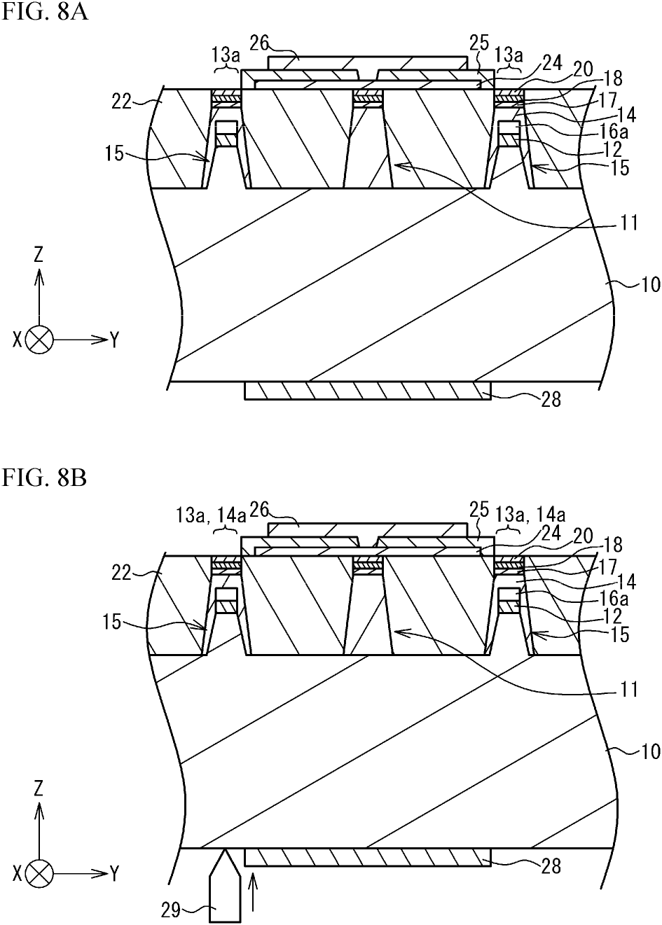

As illustrated in FIG. 7B, the contact layer 24 is epitaxially grown on the upper surface of the clad layer 20 and the upper surface of the semiconductor layer 22 by the MOVPE method or the like. As illustrated in FIG. 8A, portions of the contact layer 24 on the mesas 15 are removed by etching or the like, for example, and a portion of the contact layer 24 on the mesa 11 remains. The insulating film 25 is provided on the contact layer 24. At this time, the insulating film 25 in the regions 13a serving as the scribe line is removed, and the insulating film 25 in the regions 13b (not illustrated) is also removed. The scribe line is formed in each of the regions 13a and 13b. For example, the electrode 26 is formed on the contact layer 24 and the insulating film 25 by vacuum deposition or the like, and the electrode 28 is formed on the lower surface of the substrate 10.

Using the region 13b illustrated in FIG. 2 as the scribe line, the substrate 10 is divided by the same method as a method described with reference to FIG. 8B to form the plurality of arrays 10c. The reflective films 19 illustrated in FIG. 1B are provided on the end faces of the array 10c.

As illustrated in FIG. 8B, the array 10c is further divided to form the plurality of chips (i.e., the semiconductor device 100). A blade 29 is brought into contact with the lower surface of the substrate 10, and the blade 29 presses the substrate 10 upward from the lower surface of the substrate 10. A position where the blade 29 is brought into contact is each region 13a of the substrate 10. The semiconductor layer 14 corresponding to the region 13a is a portion 14a, and the portion 14a is more easily cracked than portions other than the portion 14a. By using the region 13a as the scribe line, the wafer including the substrate 10, the semiconductor layer 14, the clad layers 17 and 20, and the active layer 18 is cleaved along the region 13a to form the semiconductor devices 100 in a chip state.

According to the first embodiment, the mesas 15 are formed in the regions 13a and 13b serving as the scribe lines by etching with the insulating film 12 as the mask, as illustrated in FIG. 3B. As illustrated in FIG. 5A, the semiconductor layer 14 that embeds the mesas 15 is formed. The semiconductor layer 14 grows so as to laterally protrude over the insulating film 12, and forms the portions 14a in the regions 13a and 13b serving as the scribe lines. Each of the portions 14a has the crystal structure different from the other portions of the semiconductor layer 14, and is easily cracked. Therefore, the substrate 10 can be easily cleaved along the regions 13a and 13b. As a result, the generation of the foreign matters can be suppressed.

By scratching the regions 13a and 13b serving as the scribe lines in advance, it is possible to cleave the substrate 10 without laterally growing the semiconductor layer 14. However, the foreign matters are generated by the cleavage, and the foreign matters adhere to the semiconductor device, which may cause the poor appearance and the characteristic defects. According to the first embodiment, the generation of foreign matters is suppressed by cleaving the substrate 10 along the regions 13a and 13b where the portions 14a are formed. As a result, the yield of the semiconductor device is improved.

The semiconductor layers 14 and 22 are grown using the gas containing PH₃ and TMI as the raw material gas. By adjusting the growth conditions, the surface orientation dependence of the crystal growth increases, and for example, the growth to a (001) surface becomes faster.

After the growth of the semiconductor layer 14, the cavity 16a is easily formed between the insulating film 12 and the semiconductor layer 14. It is considered that the strength in the regions 13a and 13b is lower than that in the other portions due to the presence of the cavity 16a. Therefore, it becomes easy to cleave the substrate 10 along the regions 13a and 13b, and the generation of foreign matters can be suppressed. The recess 16 is formed from the cavity 16a.

It is preferable that the height H1 of the mesa 15 illustrated in FIG. 3B is 2 µm or more, for example, and the inclination angle θ is 5° or more and 45° or less, for example. The semiconductor layer 14 mainly grows upward until it reaches the upper surface of the insulating film 12 on the mesa 15, and grows so as to laterally protrude at the position above the upper surface of the insulating film 12. As a result, the portions 14a are formed on the semiconductor layer 14.

It is sufficient that the mesa 15 and the portion 14a are formed in at least a part of the plurality of regions 13a and 13b illustrated in FIG. 2. In particular, it is preferable that the mesas 15 and the portions 14a are formed in the entire of the plurality of regions 13a and the plurality of regions 13b. The mesas 15 are provided in the entire of the plurality of regions 13a and the plurality of regions 13b, and portions 14a are formed on the mesas 15. This enables the wafer to be cleaved along the regions 13a and 13b, thereby suppressing the generation of the foreign matters.

The mesa 11 is formed at the position surrounded by the mesas 15. The mesa 11 functions as a light emitting unit. That is, the semiconductor device 100 is a light emitting element that propagates the light generated by the active layer 18 along the mesa 11 and emits it to the outside. By suppressing the generation of the foreign matters, it becomes difficult for the foreign matters to adhere to emission surfaces (i.e., surfaces on the X-axis side of FIG. 1B) of the semiconductor device 100. The light is emitted without being blocked by the foreign matters.

### Second Embodiment

### Semiconductor Device

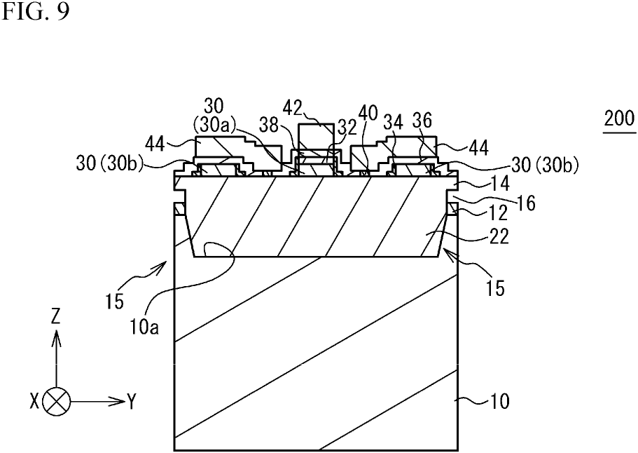

FIG. 9 is a cross-sectional view illustrating a semiconductor device 200 according to a second embodiment. A description of corresponding component elements to those in the first embodiment is omitted. As illustrated in FIG. 9, the semiconductor device 200 is a light receiving element that includes the substrate 10, insulating films 12 and 36, a passivation film 34, the semiconductor layer 14 (corresponding to the first semiconductor layer), the semiconductor layer 22, a semiconductor layer 30 (corresponding to the second semiconductor layer), a contact layer 32, electrodes 38 and 40, and plating layers 42 and 44.

The semiconductor device 200 has the mesas 15. Each of the mesas 15 is formed of the substrate 10 and surrounds the outer periphery of the semiconductor device 200 as in the example of FIG. 1B. As illustrated in FIG. 9, the semiconductor layer 14 is provided on the surface 10a of the substrate 10, embeds the mesas 15, and laterally protrudes over the mesas 15. In each mesa 15, the insulating film 12 is provided on the upper surface of the substrate 10. The recess 16 is formed between the upper surface of the insulating film 12 and the semiconductor layer 14. The mesa 11 is not provided.

Three semiconductor layers 30 are provided on the semiconductor layer 14, for example. The central one of the three semiconductor layers 30 may be referred to as a semiconductor layer 30a, and the ones located on both sides of the semiconductor layer 30a may be referred to as a semiconductor layers 30b. The semiconductor layers 30b are separated from the semiconductor layer 30a and are located between the semiconductor layer 30a and the mesas 15.

The passivation film 34 surrounding each of the semiconductor layers 30 is provided. The insulating film 36 is provided on the semiconductor layer 30b and the passivation film 34. The insulating film 36 has openings between the semiconductor layer 30a and the semiconductor layers 30b, and the electrodes 40 are provided in the openings. The electrodes 40 is electrically connected to the semiconductor layer 14. The plating layer 44 is provided on the insulating film 36 and the electrodes 40, and is electrically connected to the electrodes 40.

The contact layer 32 is provided on the upper surface of the semiconductor layer 30a, and the electrode 38 is provided on the upper surface of the contact layer 32. The electrode 38 is electrically connected to the contact layer 32. The plating layer 42 is provided on the upper surface of the electrode 38 and is electrically connected to the electrode 38. The plating layer 42 is separated from the plating layers 44 and is not electrically connected to the plating layers 44.

The semiconductor layer 30 includes, for example, an n+-InP layer, a non-doped indium phosphorus (i-InP) layer, a light absorption layer made of i-InGaAs, a graded layer made of i-InGaAsP, a field-drop layer made of n+-InP, a multiplication layer formed of i-InP, and a p-InP layer, which are stacked upward from the semiconductor layer 14. The semiconductor layer 30 may also include the other semiconductor layers. The contact layer 32 is made of p+-InGaAs, for example.

The passivation film 34 is made of a semiconductor such as InP. The insulating film 36 is made of an insulator such as SiN or SiO₂. The electrodes 38 and 40 are made of a metal such as Au. The plating layers 42 and 44 are made of a metal such as Au having a thickness of 2 to 3 µm. The electrode 38 and the plating layer 42 serve as a p-electrodes, and the electrode 40 and the plating layer 44 serve as an n-electrodes.

When light is incident on the semiconductor device 200, the light absorption layer of the semiconductor layer 30 generates carriers, and a current flows between the electrodes 38 and 40.

### Manufacturing Method

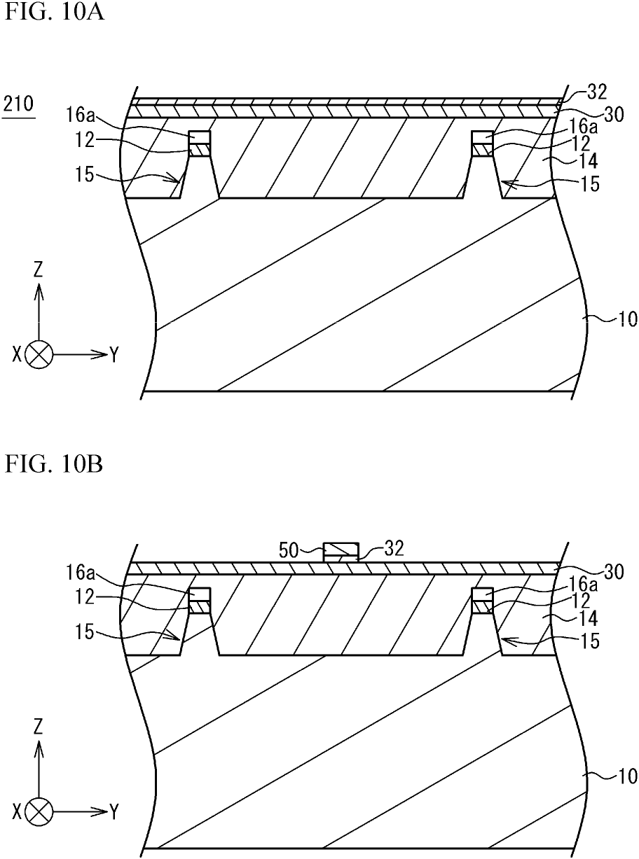

Next, a method of manufacturing the semiconductor device 200 will be described. The manufacturing method is applied to the substrate 10 in the wafer state illustrated in FIG. 2. FIGS. 10A to 13 are cross-sectional views illustrating the method for manufacturing the semiconductor device 200. The steps from FIG. 3A to FIG. 5A also apply to the second embodiment.

Also in the second embodiment, the semiconductor layer 14 is epitaxially grown by the steps of FIGS. 4A to 5A, as in the first embodiment. The semiconductor layer 14 grows upward from the upper surface of the substrate 10 and grows so as to laterally protrude over the insulating film 12. After forming the semiconductor layer 14, the semiconductor layer 30 and the contact layer 32 are epitaxially grown in this order on the upper surface of the semiconductor layer 14 by the MOVPE method, as illustrated in FIG. 10A, for example. Thereby, a semiconductor substrate 210 is formed.

As illustrated in FIG. 10B, an insulating film 50 of SiN or SiO₂ is formed on the contact layer 32. The contact layer 32 is dry-etched with SiC₄/Ar using the insulating film 50 as the mask, and a portion of the contact layer 32 near the mesas 15 is removed. A portion of the contact layer 32 surrounded by the mesas 15 remains. The electrode 38 is provided on the remaining contact layer 32, as described later.

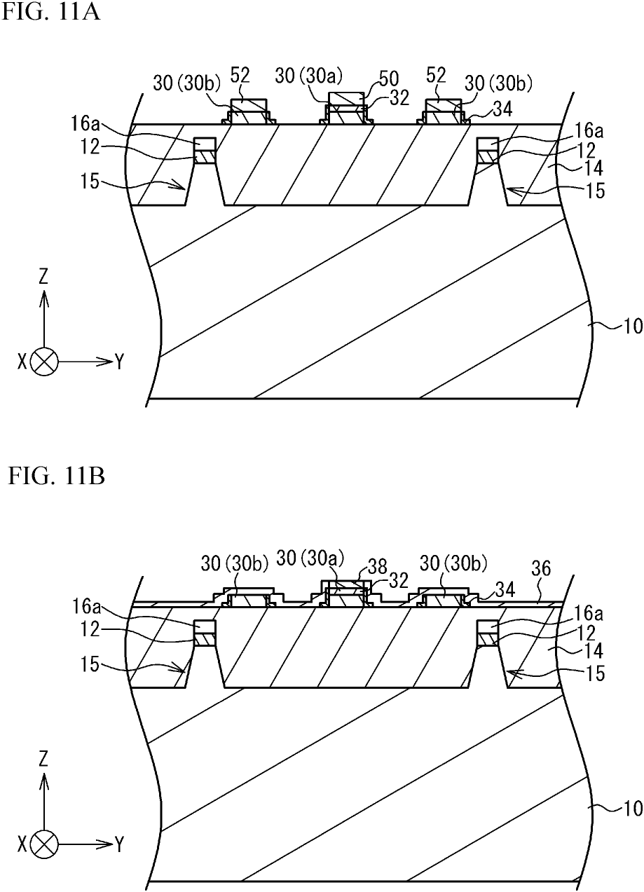

As illustrated in FIG. 11A, insulating films 52 of SiN or SiO₂ are formed on the upper surface of the semiconductor layer 30 at positions sandwiched between the contact layer 32 and the mesas 15. The dry etching is performed on the semiconductor layer 30 using the insulating films 50 and 52 as the masks. Portions of the semiconductor layer 30 protected by the insulating film 50 and the insulating film 52 remain, and an unprotected portion is removed. For example, the passivation film 34 is selectively grown on the upper surface of the semiconductor layer 14 and at a position surrounding the semiconductor layer 30, by the MOVPE method. The upper surface of the semiconductor layer 14 is exposed at a position where the passivation film 34 does not grow.

As illustrated in FIG. 11B, after removing the insulating films 50 and 52, the insulating film 36 is formed on the upper surfaces of the semiconductor layers 14 and 30, the contact layer 32, and the passivation film 34 by the CVD method or the like, for example. An opening is provided in a portion of the insulating film 36 on the contact layer 32 by etching. The electrode 38 is formed on the upper surface of the contact layer 32 exposed from the opening by vacuum deposition or the like, for example.

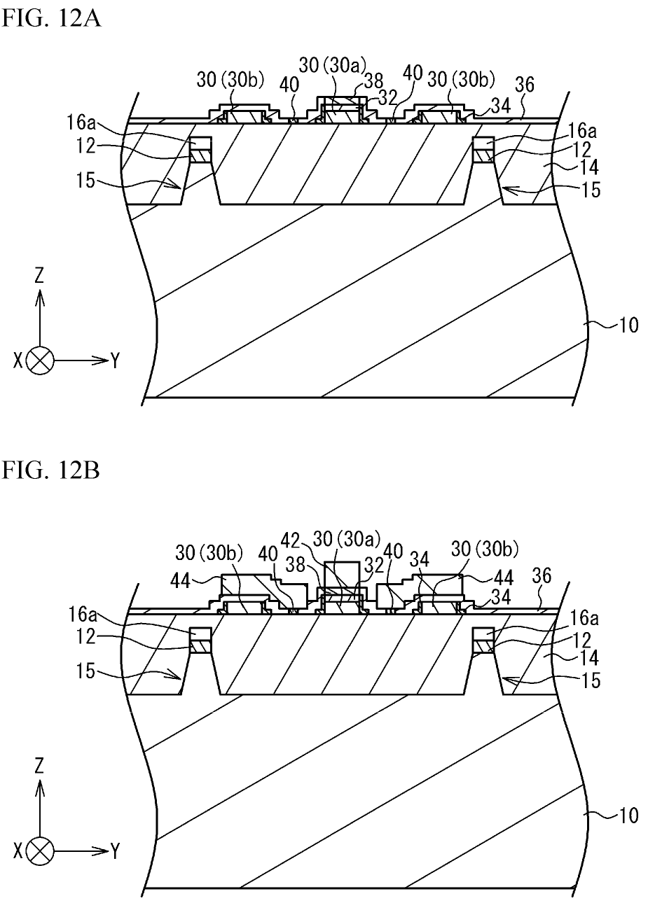

As illustrated in FIG. 12A, openings are formed in the insulating film 36 at positions between the semiconductor layer 30a and the semiconductor layers 30b by etching. The electrodes 40 are formed on the upper surface of the semiconductor layer 14 exposed from the openings by vacuum deposition or the like, for example. As illustrated in FIG. 12B, a plating process is performed to form the plating layer 42 on the upper surface of the electrode 38, and form the plating layers 44 on the upper surface of the electrodes 40.

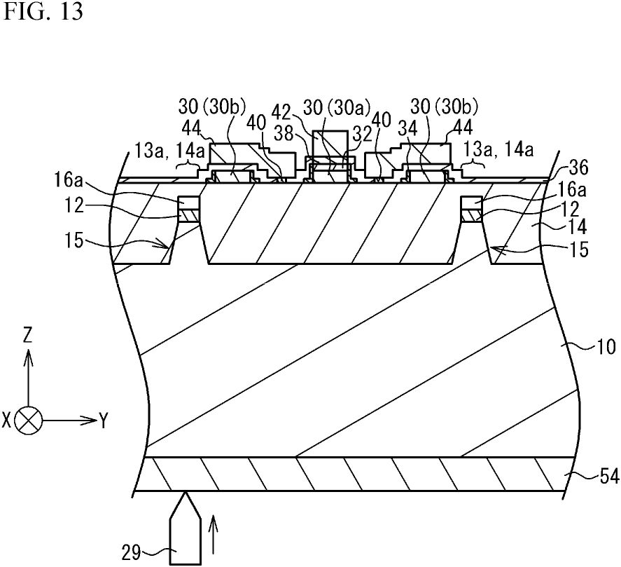

As illustrated in FIG. 13, an adhesive sheet 54 is attached to the lower surface of the substrate 10. The blade 29 is brought into contact with the lower surface of the substrate 10 via the adhesive sheet 54, and the substrate 10 is pressed upward from the lower surface of the substrate 10 by the blade 29 to cleave the wafer. The position where the blade 29 is brought into contact is each of the regions 13a and 13b serving as the scribe lines in the substrate 10. The wafer does not have to be formed in an array shape, and the reflective films 19 do not have to be provided. After the cleavage, the adhesive sheet 54 is expanded to increase a distance between adjacent semiconductor devices 200. Each of the semiconductor devices 200 is removed from the adhesive sheet 54 with tweezers or a suction device. The semiconductor devices 200 are formed by the above steps.

According to the second embodiment, the semiconductor layer 14 has the portions 14a on the mesas 15, as in the first embodiment. The portions 14a are formed in the regions 13a and 13b. Therefore, the generation of the foreign matters can be suppressed by cleaving the substrate 10 along the regions 13a and 13b. The loss of light due to the adhesion of the foreign matters is also suppressed, and the light receiving sensitivity of the semiconductor device 200 is improved.

The semiconductor device 100 according to the first embodiment is the light emitting element, and the semiconductor device 200 according to the second embodiment is the light receiving element. The present disclosure can be applied to semiconductor devices other than optical devices such as the light emitting element and the light receiving element.

In the embodiment of the present disclosure, the mesa 15 is formed in the region serving as the scribe line, and laterally promoted growth of the semiconductor layer 14 is performed over the mesa 15. Instead of this embodiment, forming an insulating film in the region serving as the scribe line on the substrate 10 and performing the laterally promoted growth of the semiconductor layer 14 over the insulating film can also have the same effect as forming the mesa 15.

The embodiments of the present disclosure have been described in detail. However, the scope of the present invention is not limited to the specific embodiments of the disclosure. It is to be understood that the scope of the present invention is defined in the appended claims and includes equivalence of the description of the claims and all changes within the scope of the claims.

What is claimed is:

1. A method for manufacturing a semiconductor device comprising:
selectively forming an insulating film on a region of a substrate serving as a scribe line; and
forming a first semiconductor layer in a state where a cavity is provided on the insulating film;
wherein the cavity is buried in the first semiconductor layer.

2. The method for manufacturing the semiconductor device according to claim 1, further comprising:
etching the substrate using the insulating film as a mask to form a mesa before forming the first semiconductor layer,
wherein the first semiconductor layer is formed in a peripheral region of the mesa.

3. The method for manufacturing the semiconductor device according to claim 1,
wherein the first semiconductor layer is formed by applying a growth gas of phosphine and trimethylindium, a flow rate of the phosphine being greater than a flow rate of the trimethylindium.

4. The method for manufacturing the semiconductor device according to claim 1, wherein the cavity comprises a plurality of cavities, the method further comprising:
forming a second semiconductor layer on the first semiconductor layer; and
forming a light emitting element or a light receiving element to the second semiconductor layer in a region between two cavities among the plurality of cavities.

5. The method for manufacturing the semiconductor device according to claim 1, further comprising:
dividing the substrate and the first semiconductor into a plurality of pieces by pressing at a position on a line perpendicular to a surface of the substrate and passing through the cavity.

6. The method for manufacturing the semiconductor device according to claim 5,
wherein the position is at a surface of the substrate opposite to a surface on which the first semiconductor layer is formed.
